(19) United States
(12) Patent Application Publication
(10) Pub. No.: US 2024/0274692 A1
(43) Pub. Date: Aug. 15, 2024

(54) METHOD OF MANUFACTURING SEMICONDUCTOR DEVICE

(71) Applicant: Renesas Electronics Corporation, Tokyo (JP)

(72) Inventor: Yuya ABIKO, Tokyo (JP)

(21) Appl. No.: 18/522,040

(22) Filed: Nov. 28, 2023

(30) Foreign Application Priority Data
Feb. 9, 2023 (JP) 2023-018587

(51) Int. Cl. H01L 29/66; H01L 21/3213; H01L 29/40

(52) U.S. Cl. CPC H01L 29/66734; H01L 21/32135; H01L 29/401; H01L 29/407

(57) ABSTRACT

Reliability of a semiconductor device is improved. A field plate electrode is formed on an insulating film inside a trench. Next, by an isotropic etching process to the insulating film, the insulating film is thinned, and an upper portion of the field plate electrode is exposed from the insulating film. Next, an isotropic etching process (chemical dry etching process) is performed to the field plate electrode exposed from the insulating film. In this manner, a corner of the upper portion of the field plate electrode is chamfered or rounded, and therefore, a concentration of electric field at the upper portion of the field plate electrode can be moderated.

### CROSS-REFERENCE TO RELATED APPLICATION

The disclosure of Japanese Patent Application No. 2023-018587 filed on Feb. 9, 2023, including the specification, drawings and abstract is incorporated herein by reference in its entirety.

### BACKGROUND

The present invention relates to a method of manufacturing a semiconductor device, and particularly relates to a method of manufacturing a semiconductor device including an insulating film formed inside a trench.

A trench gate structure in which a gate electrode is embedded inside a trench is applied to a semiconductor device including a semiconductor element such as a power metal oxide semiconductor field effect transistor (MOSFET). One type of the trench gate structure is a split-gate structure in which a field plate electrode is formed below the trench while a gate electrode is formed on the trench. To the field plate electrode, a source potential is supplied from a source electrode. By the field plate electrode, a depletion layer is spread in a drift region, so that the drift region can have a higher concentration, and a resistance of the drift region can be decreased.

There is disclosed technique listed below.

[Patent Document 1] Japanese Unexamined Patent Application Publication No. 2011-199109

For example, the Patent Document 1 discloses the MOSFET with the split-gate structure. In the Patent Document 1, a polysilicon film is formed inside the trench and on a semiconductor substrate, and the polysilicon film is etched back by an anisotropic etching process, so that the field plate electrode is formed inside the trench. Further, an insulating film between a gate electrode and the field plate electrode is formed by a thermal oxidization method.

### SUMMARY

When the field plate electrode is formed by the etching-back, a corner of an upper portion of the field plate electrode is easily protruded. Thus, electric field easily concentrates on the protruded corner, and leak current is easily caused between the gate electrode and the field plate electrode. Also, there is a risk of deterioration of dielectric breakdown of the insulating film formed between the gate electrode and the field plate electrode. Therefore, there is a problem of decrease of reliability of the semiconductor device.

Other objects and novel characteristics will be apparent from the description of the present specification and the accompanying drawings.

The outline of the typical aspects of the embodiments disclosed in the present application will be briefly described as follows.

A method of manufacturing a semiconductor device according to one embodiment, steps includes of: (a) preparing a semiconductor substrate of a first conductive type, the semiconductor substrate having an upper surface and a lower surface; (b) after the step of (a), forming a trench in the semiconductor substrate at the upper surface of the semiconductor substrate; (c) after the step of (b), forming a first insulating film inside the trench and on the upper surface of the semiconductor substrate; (d) after the step of (c), forming a field plate electrode on the first insulating film located inside the trench; (e) after the step of (d), thinning the first insulating film, and exposing an upper portion of the field plate electrode from the first insulating film; (f) after the step of (e), performing an isotropic etching process to the upper portion of the field plate electrode exposed from the first insulating film; (g) after the step of (f), removing the first insulating film located on the upper surface of the semiconductor substrate, and recessing the first insulating film located inside the trench such that an upper surface of the first insulating film located inside the trench is positioned lower than the upper portion of the field plate electrode in cross-sectional view; and (h) after the step of (g), in cross-sectional view, forming a gate insulating film inside the trench positioned over the upper surface of the first insulating film, and forming a second insulating film on an upper surface of the upper portion of the field plate electrode and on a side surface of the field plate electrode exposed from the first insulating film in the step of (g).

According to one embodiment, reliability of the semiconductor device can be improved.

### BRIEF DESCRIPTIONS OF THE DRAWINGS

FIG. 1 is a plan view illustrating an entire semiconductor device according to a first embodiment.

FIG. 2 is a plan view of a principal part of the semiconductor device according to the first embodiment.

FIG. 3 is a plan view of a principal part of the semiconductor device according to the first embodiment.

FIG. 4 is cross-sectional views illustrating the semiconductor device according to the first embodiment.

FIG. 5 is cross-sectional views illustrating a step of manufacturing the semiconductor device according to the first embodiment.

FIG. 6 is cross-sectional views illustrating a step of manufacturing the semiconductor device, continued from FIG. 5.

FIG. 7 is cross-sectional views illustrating a step of manufacturing the semiconductor device, continued from FIG. 6.

FIG. 8 is cross-sectional views illustrating a step of manufacturing the semiconductor device, continued from FIG. 7.

FIG. 9 is cross-sectional views illustrating a step of manufacturing the semiconductor device, continued from FIG. 8.

FIG. 10 is cross-sectional views illustrating a step of manufacturing the semiconductor device, continued from FIG. 9.

FIG. 11 is cross-sectional views illustrating a step of manufacturing the semiconductor device, continued from FIG. 10.

FIG. 12 is cross-sectional views illustrating a step of manufacturing the semiconductor device, continued from FIG. 11.

FIG. 13 is cross-sectional views illustrating a step of manufacturing the semiconductor device, continued from FIG. 12.

FIG. 14 is cross-sectional views illustrating a step of manufacturing the semiconductor device, continued from FIG. 13.

FIG. 15 is cross-sectional views illustrating a step of manufacturing the semiconductor device, continued from FIG. 14.

FIG. 16 is cross-sectional views illustrating a step of manufacturing the semiconductor device, continued from FIG. 15.

FIG. 17 is cross-sectional views illustrating a step of manufacturing the semiconductor device, continued from FIG. 16.

FIG. 18 is cross-sectional views illustrating a step of manufacturing the semiconductor device, continued from FIG. 17.

FIG. 19 is cross-sectional views illustrating a step of manufacturing the semiconductor device, continued from FIG. 18.

FIG. 20 is cross-sectional views illustrating a step of manufacturing the semiconductor device, continued from FIG. 19.

FIG. 21 is cross-sectional views illustrating a step of manufacturing the semiconductor device, continued from FIG. 20.

FIG. 22 is a cross-sectional view illustrating a step of manufacturing a semiconductor device according to a second embodiment.

FIG. 23 is cross-sectional views illustrating a step of manufacturing a semiconductor device according to first examined example.

FIG. 24 is cross-sectional views illustrating a step of manufacturing the semiconductor device, continued from FIG. 23.

FIG. 25 is a cross-sectional view illustrating a step of manufacturing a semiconductor device according to a second examined example.

### DETAILED DESCRIPTION

Hereinafter, embodiments will be described in detail with reference to the accompanying drawings. Note that components having the same function are denoted by the same reference signs throughout all the drawings for explaining the embodiments, and the repetitive description thereof will be omitted. In addition, the description of the same or similar portions is not repeated in principle unless otherwise particularly required in the following embodiments.

An X direction, a Y direction, and a Z direction described in the present application cross with one another, and are orthogonal to one another. In the present application, the Z direction will be described as a vertical direction, a height direction, or a depth direction of a structure. The expressions such as “plan view” or “planar view” used in the present application mean that a “plane” made of the X direction and the Y direction is viewed in the Z direction.

### First Embodiment

### <Structure of Semiconductor Device>

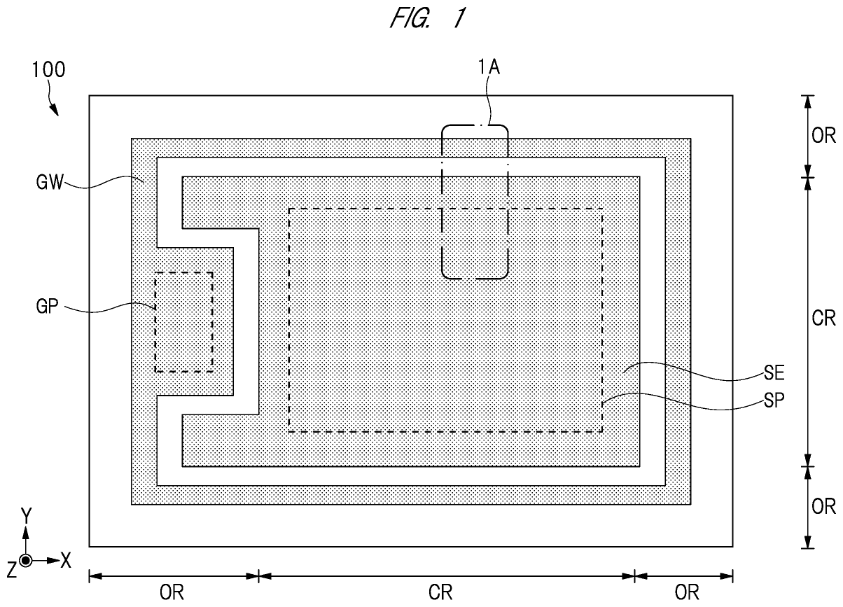

A semiconductor device 100 according to a first embodiment will be described below with reference to FIGS. 1 to 4. Main features of the present application are structures of a field plate electrode FP and an insulating film IF2 and steps of manufacturing these components, and such features will be described in detail later.

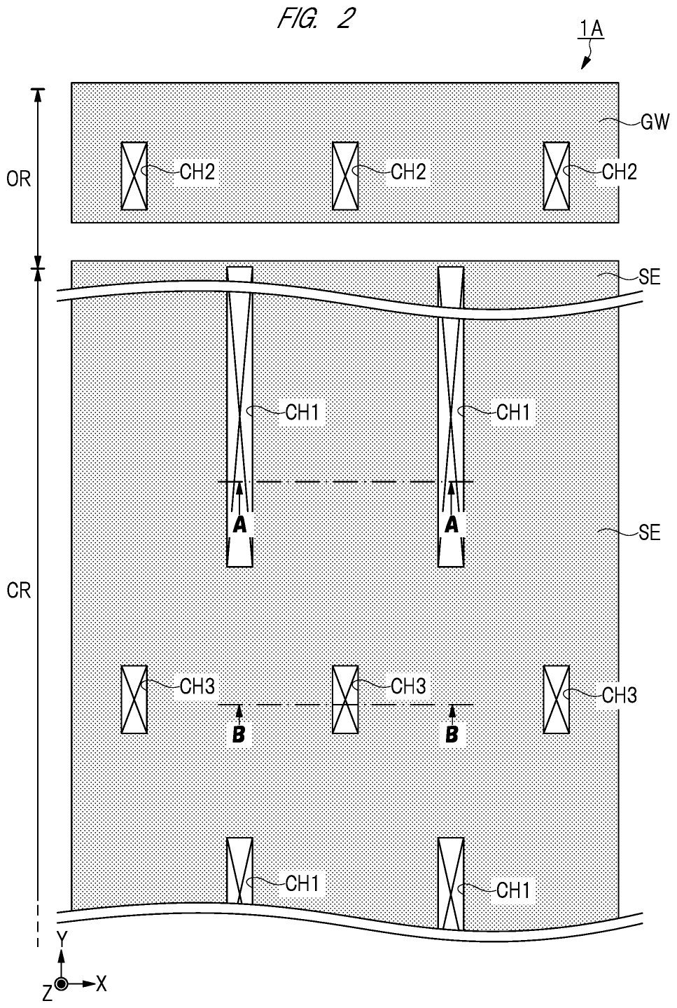

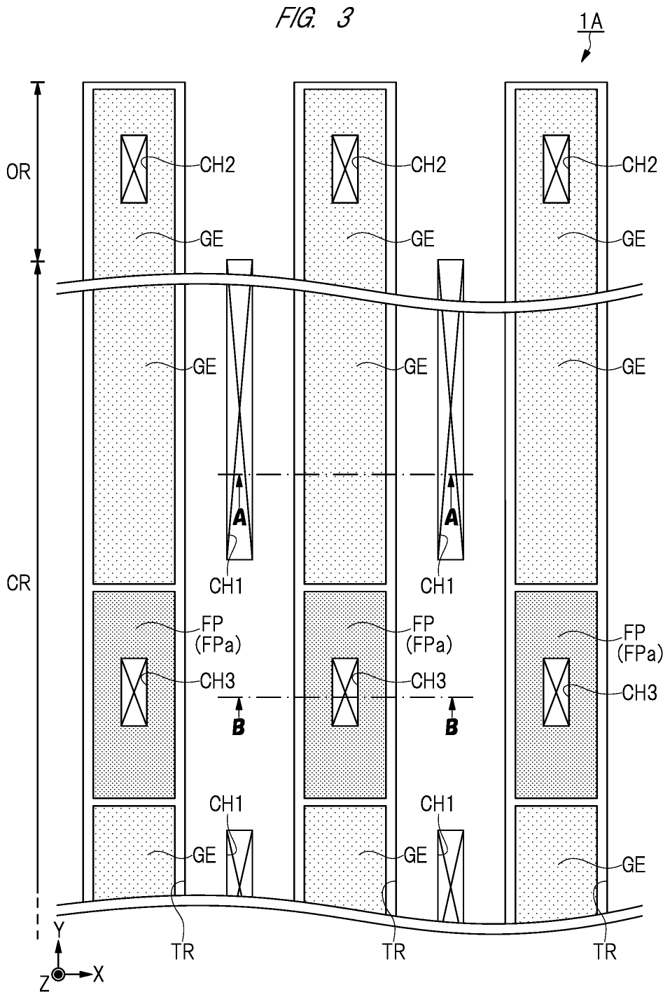

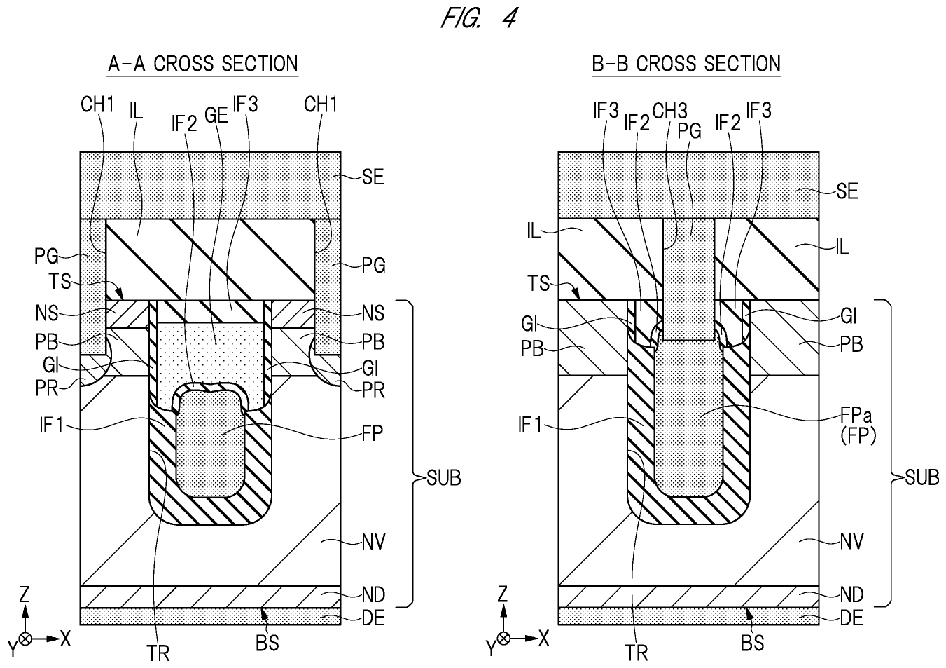

FIG. 1 is a plan view of a semiconductor chip as the semiconductor device 100. Each of FIGS. 2 and 3 is a plan view of a principal part of an enlarged region 1A of FIG. 1. FIG. 3 illustrates a structure below FIG. 2 and mainly illustrates a trench gate structure formed in a semiconductor substrate SUB. Positions of holes CH1 to CH3 of FIG. 2 match with positions of holes CH1 to CH3 of FIG. 3, respectively. FIG. 4 is cross-sectional views taken along line A-A and line B-B of FIGS. 2 and 3.

FIG. 1 mainly illustrates a wiring pattern formed on the semiconductor substrate SUB. The semiconductor device 100 includes a cell region CR and an outer region OR surrounding the cell region CR in plan view. Main semiconductor elements such as a plurality of MOSFETs are formed in the cell region CR. The outer region OR is used for connecting a gate wiring GW to a gate electrode GE and for forming a structure functioning as a termination region.

As illustrated in FIGS. 1 and 2, the cell region CR is covered with a source electrode SE. The gate wiring GW surrounds the source electrode SE in plan view. Although not illustrated here, the source electrode SE and the gate wiring GW are covered with a protective film such as a polyimide film. Openings are provided in a part of the protective film, and the source electrode SE and the gate wiring GW exposed at the openings serve as a source pad SP and a gate pad GP, respectively. When external connection members are connected onto the source pad SP and the gate pad GP, the semiconductor device 100 is electrically connected to other semiconductor chip, a lead frame, a wiring substrate, or the like. Note that the external connection member is, for example, a wire made of gold or copper, or a clip made of copper plate or the like.

As illustrated in FIG. 3, a plurality of trenches TR are formed in the semiconductor substrate SUB. A plurality of trenches TR are formed in the cell region CR in a stripe shape, and extend in the Y direction and are mutually adjacent in the X direction.

In the cell region CR, a field plate electrode FP is formed at the lower portion of the trench TR inside the trench TR, and a gate electrode GE is formed at the upper portion of the trench TR. A part of the field plate electrode FP configures a contact portion FPa. The contact portion FPa is formed in a part of the cell region CR. The field plate electrode FP configuring the contact portion FPa is formed not only at the lower portion of the trench TR but also at the upper portion of the trench TR inside the trench TR.

A cross-sectional structure of the semiconductor device 100 will be described below with reference to FIG. 4.

As illustrated in FIG. 4, the semiconductor device 100 includes the n-type semiconductor substrate SUB having an upper surface TS and a lower surface BS. The semiconductor substrate SUB is made of n-type silicon. The semiconductor substrate SUB includes a low-concentration n-type drift region NV. Here, the n-type semiconductor substrate SUB itself configures the drift region NV. Note that the semiconductor substrate SUB may have a stacked structure made of an n-type silicon substrate and an n-type semiconductor layer being grown on the n-type silicon substrate while being doped with phosphorus (P) by an epitaxial growth method. In this case, the low-concentration n-type semiconductor layer configures the drift region NV while the high-concentration n-type silicon substrate configures a drain region ND.

The n-type drain region ND is formed in the semiconductor substrate SUB on the lower surface BS of the semiconductor substrate SUB. The drain region ND has a higher impurity concentration than that of the drift region NV. The drain electrode DE is formed on the lower surface BS of the semiconductor substrate SUB. The drain electrode DE is made of, for example, a single-layer metal film such as an aluminum film, a titanium film, a nickel film, a gold film, or a silver film, or a stacked film in which these metal films are appropriately stacked. The drain region ND and the drain electrode DE are formed over the cell region CR and the outer region OR. To the semiconductor substrate SUB (the drain region ND and the drift region NV), a drain potential is supplied from the drain electrode DE.

Trenches TR with a predetermined depth from the upper surface TS of the semiconductor substrate SUB are formed in the semiconductor substrate SUB on the upper surface TS of the semiconductor substrate SUB. A depth of the trench TR is, for example, equal to or larger than 5 μm and equal to or smaller than 7 μm. Inside the trench TR, the field plate electrode FP is formed at the lower portion of the trench TR via an insulating film IF1 while the gate electrode GE is formed at the upper portion of the trench TR via a gate insulating film GI.

The upper surface of the insulating film IF1 is lower than the upper surface of the field plate electrode FP. The gate insulating film GI is formed on the insulating film IF1 inside the trench TR. An insulating film IF2 is formed on the upper surface of the field plate electrode FP and also side surface of the field plate electrode FP which are exposed from the insulating film IF1. The gate electrode GE is formed also between the field plate electrode FP exposed from the insulating film IF1 and the semiconductor substrate SUB via the gate insulating film GI and the insulating film IF2.

The insulating film IF1 is formed between the semiconductor substrate SUB and the field plate electrode FP. The insulating film IF2 is formed between the gate electrode GE and the field plate electrode FP. The gate insulating film GI is formed between the semiconductor substrate SUB and the gate electrode GE. The semiconductor substrate SUB, the gate electrode GE, and the field plate electrode FP are electrically insulated from one another by the insulating films.

Each of the field plate electrode FP and the gate electrode GE is made of, for example, a polycrystalline silicon film doped with n-type impurity. An impurity concentration of each of the polycrystalline silicon films is higher than an impurity concentration of the drift region NV, and is, for example, 4.0×10²⁰/cm³.

Each of the insulating film IF1, the insulating film IF2 and the gate insulating film GI is made of, for example, a silicon oxide film. A thickness of the insulating film IF1 is larger than each thickness of the insulating film IF2 and the gate insulating film GI. The thickness of the insulating film IF1 is, for example, equal to or larger than 400 nm and equal to or smaller than 600 nm. Each thickness of the insulating film IF2 and the gate insulating film GI is, for example, equal to or larger than 50 nm and equal to or smaller than 70 nm. An insulating film IF3 is formed on the gate electrode GE. The insulating film IF3 is made of, for example, a silicon oxide film.

A p-type body region PB is formed to be shallower than the trench TR in the semiconductor substrate SUB on the upper surface TS of the semiconductor substrate SUB. An n-type source region NS is formed in the body region PB. The source region NS has a higher impurity concentration than that of the drift region NV.

An interlayer insulating film IL is formed on the upper surface TS of the semiconductor substrate SUB to cover the trench TR. The interlayer insulating film IL is made of, for example, a silicon oxide film. A thickness of the interlayer insulating film IL is, for example, equal to or larger than 700 nm and equal to or smaller than 900 nm.

A hole CH1 which penetrates the interlayer insulating film IL and the source region NS and reaches the body region PB is formed in the interlayer insulating film IL. A high-concentration diffusion region PR is formed at the lower portion of the hole CH1 in the body region PB. The high-concentration diffusion region PR has a higher impurity concentration than that of the body region PB.

The source electrode SE is formed on the interlayer insulating film IL. The source electrode SE is electrically connected to the source region NS, the body region PB, and the high-concentration diffusion region PR via the hole CH1, and supplies a source potential to these impurity regions.

As illustrated in the cross section B-B in FIG. 4, a part of the field plate electrode FP configures the contact portion FPa of the field plate electrode FP. The upper surface of the insulating film IF1 in contact with the field plate electrode FP other than the contact portion FPa is lower than the upper surface of the insulating film IF1 in contact with the contact portion FPa. That is, the upper surface of the insulating film IF1 in the cross section A-A is positioned at a depth that is equal to or larger than 300 nm and equal to or smaller than 400 nm from the upper surface TS of the semiconductor substrate SUB. The upper surface of the insulating film IF1 in the cross section B-B is positioned at a depth that is equal to or larger than 50 nm and equal to or smaller than 100 nm from the upper surface TS of the semiconductor substrate SUB.

The insulating film IF2 is formed on the upper surface of the contact portion FPa and also side surface of the contact portion FPa which are exposed from the insulating film IF1. The insulating film IF3 is formed on the insulating film IF2. Note that the insulating film IF3 may not be formed as described later.

A hole CH3 which penetrates the interlayer insulating film IL, the insulating film IF3 and the insulating film IF2 and which reaches the contact portion FPa is formed in the interlayer insulating film IL. The source electrode SE is electrically connected to the field plate electrode FP via the hole CH3, and supplies a source potential to the field plate electrode FP.

Although not illustrated here, a hole CH2 which penetrates the interlayer insulating film IL and the insulating film IF3 and which reaches the gate electrode GE is formed in the interlayer insulating film IL. The gate wiring GW is electrically connected to the gate electrode GE via the hole CH2, and supplies a gate potential to the gate electrode GE.

A plug PG is embedded inside each of the holes CH1 to CH3. A plug PG is made of, for example, a barrier metal film and a conductive film formed on the barrier metal film. The barrier metal film is made of a stacked film of a titanium film and a titanium nitride film. The conductive film is, for example, a tungsten film.

Each of the source electrode SE and the gate wiring GW is made of, for example, a barrier metal film and a conductive film formed on the barrier metal film. The barrier metal film is, for example, a titanium tungsten film, and the conductive film is, for example, an aluminum alloy film to which copper or silicon is added.

In the first embodiment, the corner of the upper portion of the field plate electrode FP is chamfered or rounded. Thus, regions where electric field concentrates are uniform between the gate electrode GE and the field plate electrode FP. That is, since the concentration of the electric field is reduced, a risk of occurrence of leak current is suppressed between the gate electrode GE and the field plate electrode FP. Therefore, reliability of the semiconductor device 100 can be improved.

A method of manufacturing a semiconductor device in order to form a structure of such a field plate electrode FP will be described below.

### <Method of Manufacturing Semiconductor Device>

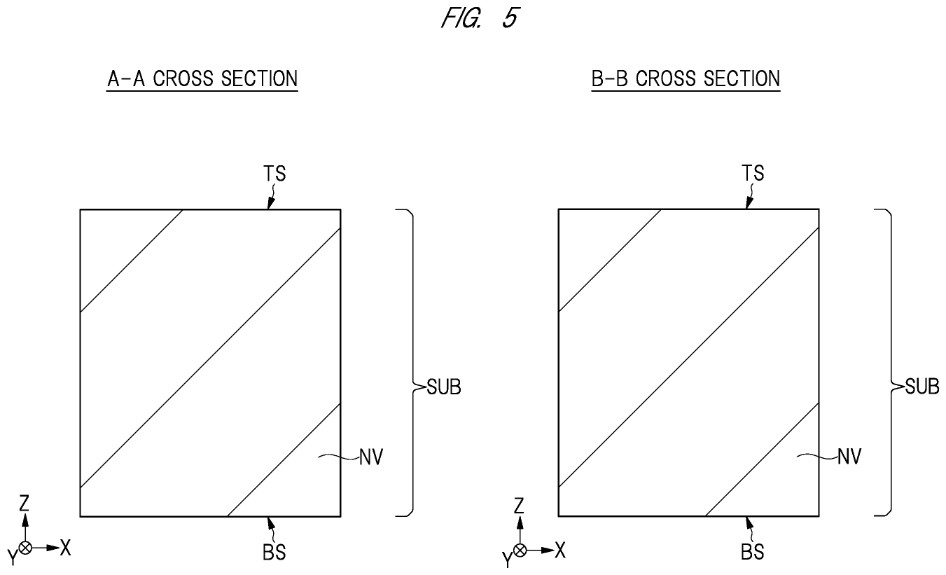

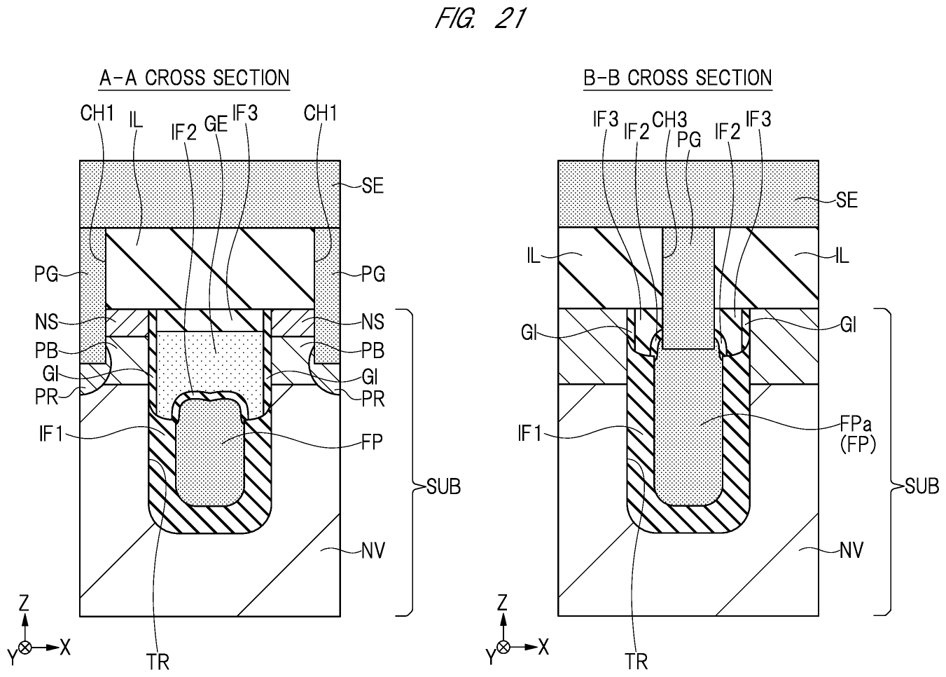

Each manufacturing step in the method of manufacturing the semiconductor device 100 will be described below with reference to FIGS. 5 to 21.

As illustrated in FIG. 5, first, the n-type semiconductor substrate SUB having the upper surface TS and the lower surface BS is prepared. As described above, the semiconductor substrate SUB may have a stacked structure made of an n-type silicon substrate and an n-type semiconductor layer formed on the silicon substrate by an epitaxial growth method.

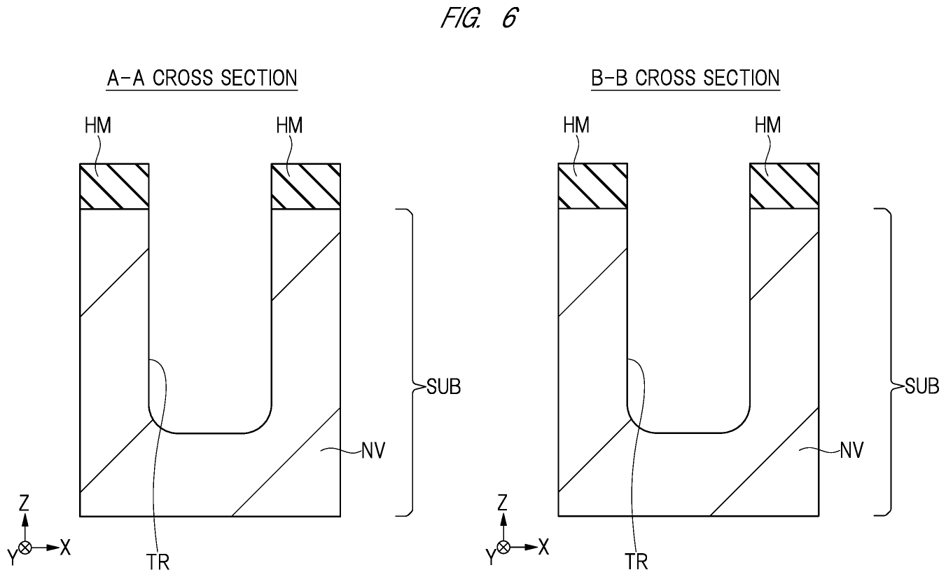

Next, as illustrated in FIG. 6, the trench TR is formed in the semiconductor substrate SUB on the upper surface TS of the semiconductor substrate SUB.

First, on the semiconductor substrate SUB, for example, a silicon oxide film is formed by, for example, a CVD method. Next, the silicon oxide film is patterned by a photolithography technique and an anisotropic etching process to form a hard mask HM. Next, an anisotropic etching process is performed while using the hard mask HM as a mask to form the trench TR in the semiconductor substrate SUB. The trench TR is formed in the semiconductor substrate SUB to extend from the upper surface TS toward the lower surface BS. Then, the hard mask HM is removed by, for example, a wet etching process using a solution containing hydrofluoric acid.

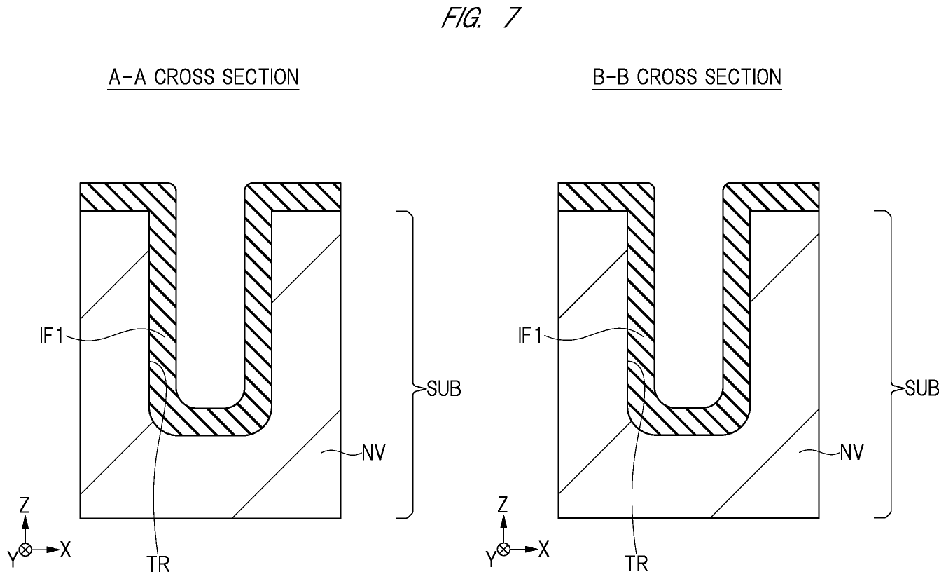

Next, as illustrated in FIG. 7, the insulating film IF1 is formed inside the trench TR and on the semiconductor substrate SUB. The insulating film IF1 is, for example, a silicon oxide film formed by a thermal oxidization process. Note that the insulating film IF1 may be a stacked film made of a first silicon oxide film formed by a thermal oxidization process and a second silicon oxide film formed on the first silicon oxide film by a CVD method.

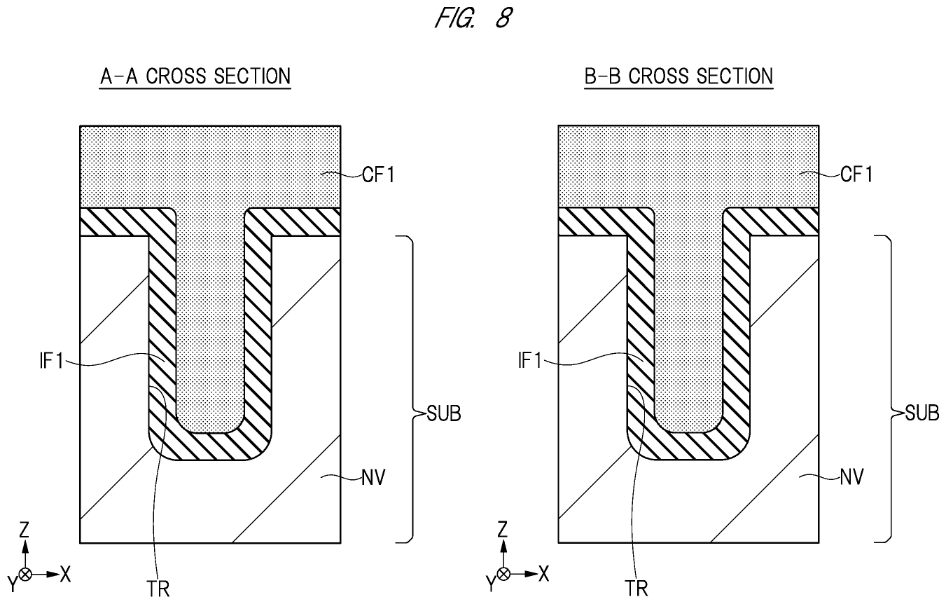

Next, as illustrated in FIG. 8, the conductive film CF1 is formed on the insulating film IF1 by, for example, a CVD method to fill inside of the trench TR. The conductive film CF1 is, for example, an n-type polycrystalline silicon film. In order to favorably embed the conductive film CF1 into the trench TR, the conductive film CF1 may be formed by two separate processes for formation of a first polycrystalline silicon film and formation of a second polycrystalline silicon film.

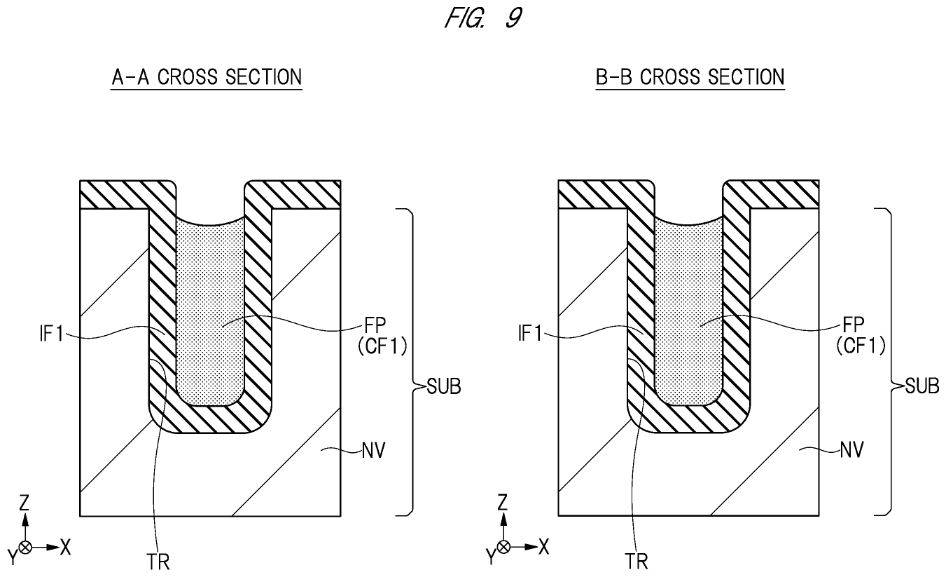

Next, as illustrated in FIG. 9, the conductive film CF1 formed (located) outside the trench TR is removed to form the conductive film CF1 remaining inside the trench TR as the field plate electrode FP.

First, the conductive film CF1 formed (located) outside the trench TR is removed by, for example, a polishing process using a chemical mechanical polishing (CMP) method. Next, for example, by an anisotropic etching process using SF₆ gas, the upper surface of the conductive film CF1 located inside the trench TR is recessed. In this manner, the field plate electrode FP is formed inside the trench TR.

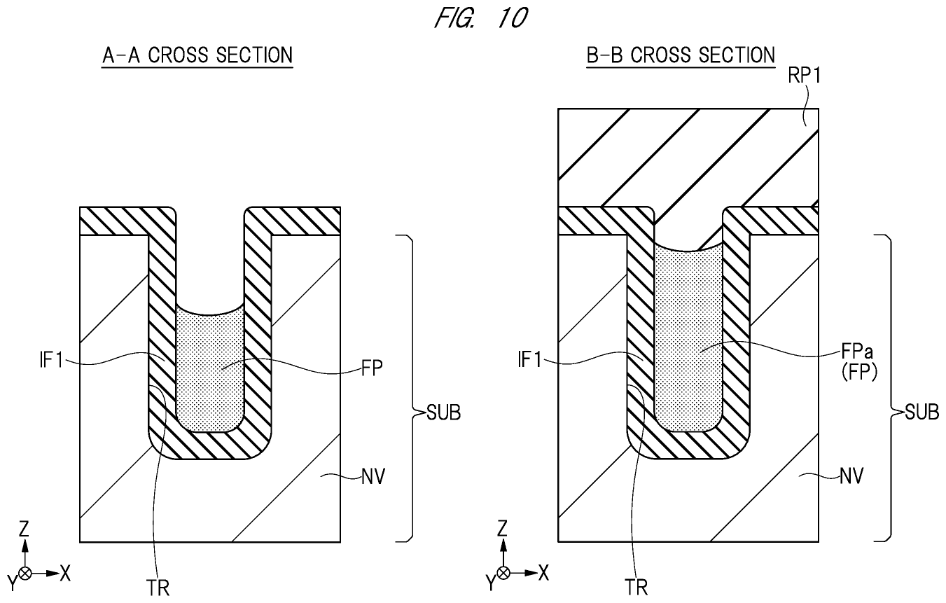

Next, as illustrated in FIG. 10, in order to leave a part of the field plate electrode FP as the contact portion FPa, other part of the field plate electrode FP is selectively etched (namely, the field plate electrode FP is selectively recessed).

First, as illustrated in the cross section B-B, a resist pattern RP1 selectively covering a part of the field plate electrode FP which is to be the contact portion FPa is formed. Next, the field plate electrode FP is patterned by, for example, an anisotropic etching process using SF₆ gas while using the resist pattern RP1 as a mask. That is, as illustrated in the cross section A-A, other part of the field plate electrode FP is selectively etched (namely, the field plate electrode FP is selectively recessed). A not-recessed part of the field plate electrode FP is to be the contact portion FPa. Then, the resist pattern RP1 is removed by an ashing process.

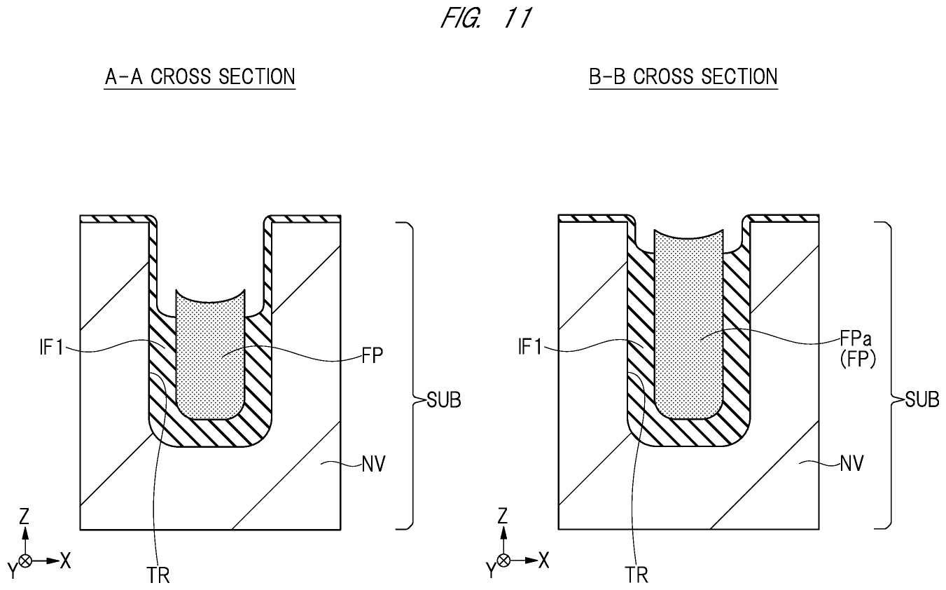

Next, as illustrated in FIG. 11, by an isotropic etching process to the insulating film IF1, the insulating film IF1 is thinned, and the upper portion of the field plate electrode FP is exposed from the insulating film IF1. At this time, the upper portion of the contact portion FPa is also exposed from the insulating film IF1. At this stage, note that the insulating film IF1 on the upper surface TS of the semiconductor substrate SUB and inside the trench TR is not completely removed. The isotropic etching process is, for example, a wet etching process using a solution containing hydrofluoric acid.

By the anisotropic etching process of FIGS. 9 and 10, the exposed corner of the upper portion of the field plate electrode FP and the contact portion FPa is protruded.

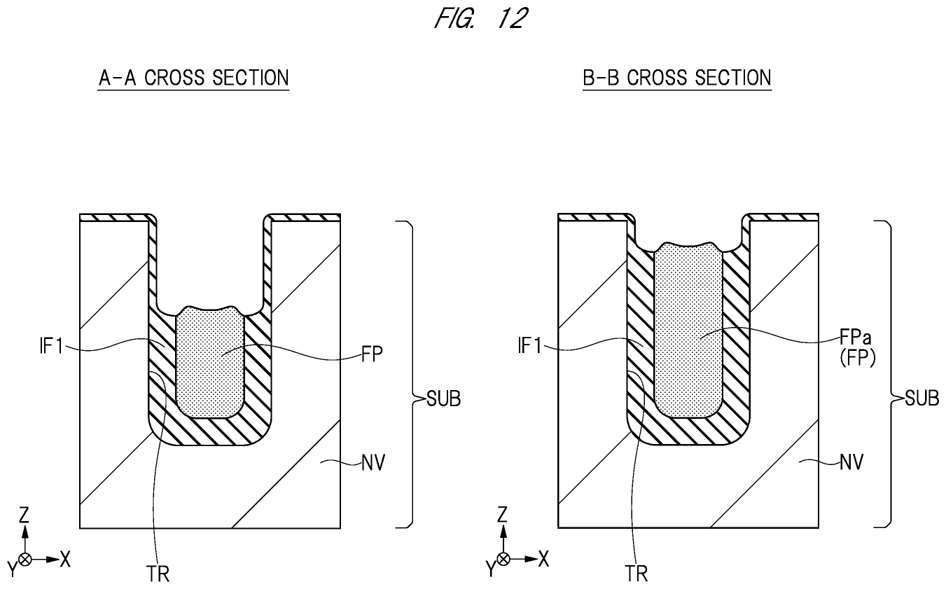

Next, as illustrated in FIG. 12, the upper portion of the field plate electrode FP exposed from the insulating film IF1 is isotropically etched. Similarly, the upper portion of the contact portion FPa exposed from the insulating film IF1 is isotropically etched. The isotropic etching process is a chemical dry etching process using CF4 gas. In this manner, the corner of the upper portion of the field plate electrode FP and the contact portion FPa is chamfered or rounded.

At the time of the isotropic etching process, the thinned insulating film IF1 on the upper surface TS of the semiconductor substrate SUB and inside the trench TR functions as an etching stopper.

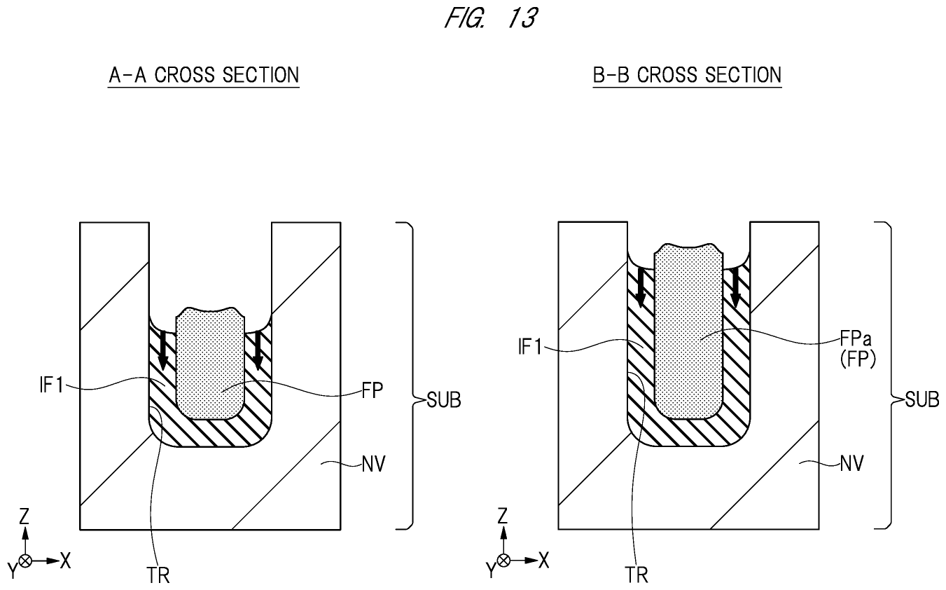

Next, as illustrated in FIG. 13, by isotropic etching onto the insulating film IF1, the insulating film IF1 on the upper surface TS of the semiconductor substrate SUB is removed. At the same time, the insulating film IF1 located inside the trench TR is recessed in a direction of an arrow of FIG. 13 so that the upper surface of the insulating film IF1 located inside the trench TR is lower than the upper portion of the field plate electrode FP in cross-sectional view.

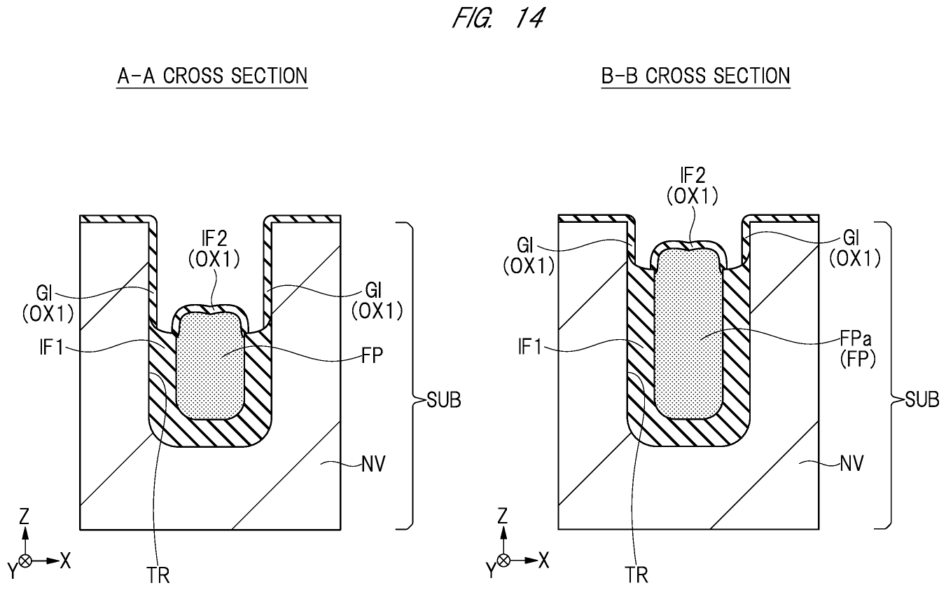

Next, as illustrated in FIG. 14, the gate insulating film GI is formed inside the trench TR positioned on the upper surface of the insulating film IF1 recessed by the isotropic etching process. At the same time, the insulating film IF2 is formed on the (upper) surface of the upper portion of the field plate electrode FP and the side surface of the field plate electrode FP newly exposed from the insulating film IF1 by the isotropic etching process.

Each of the gate insulating film GI and the insulating film IF2 is made of a silicon oxide film OX1. The silicon oxide film OX1 is formed by a dry oxidization process. The dry oxidization process is, for example, a thermal oxidization process using oxygen gas under a condition of a temperature that is equal to or higher than 1000° ° C., and that is equal to or lower than 1200° C. A thickness of the silicon oxide film OX1 is, for example, equal to or larger than 50 nm and equal to or smaller than 70 nm.

### <Comparison Between Examined Examples and First Embodiment>

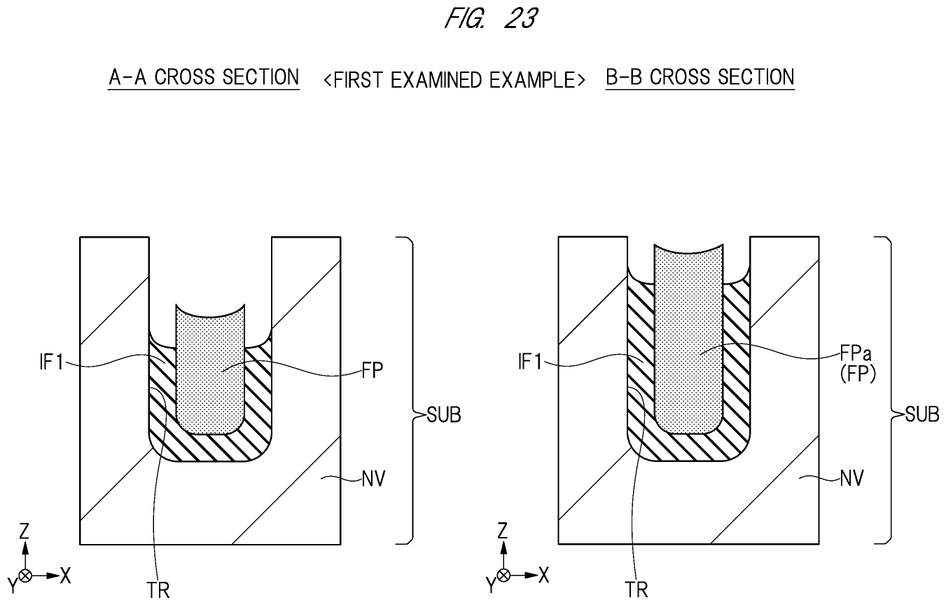

With reference to FIGS. 23 to 25, semiconductor devices according to first and second examined examples examined by the present inventors will be described herein.

In the first examined example, as illustrated in FIG. 23, by a single isotropic etching process after the field plate electrode FP including the contact portion FPa is formed, the insulating film IF1 on the upper surface TS of the semiconductor substrate SUB is removed while the insulating film IF1 located inside the trench TR is recessed. The chemical dry etching process of FIG. 12 is not performed in the first examined example.

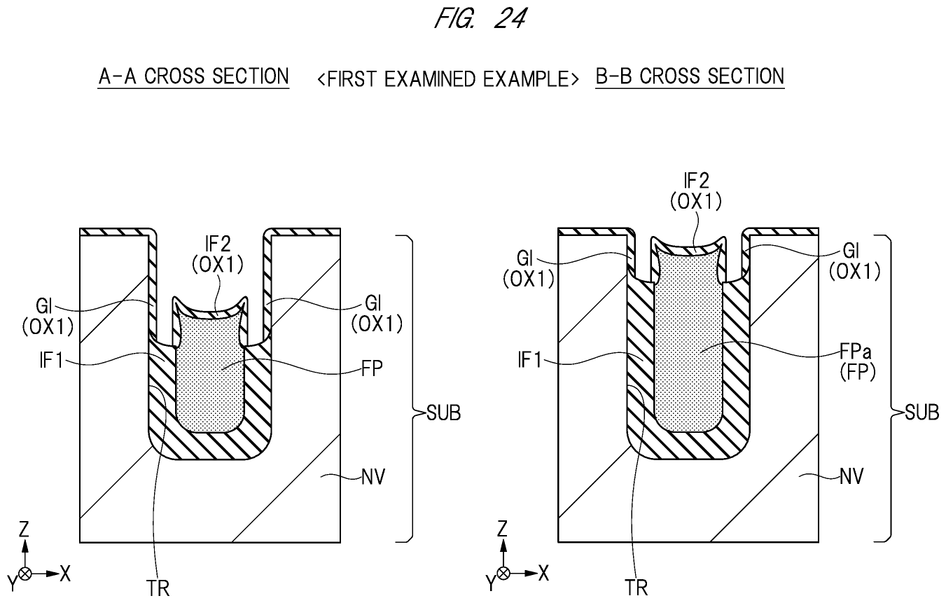

Then, as illustrated in FIG. 24, a dry oxidization process is performed to form the silicon oxide film OX1 (the gate insulating film GI and the insulating film IF2).

The first examined example is different from the first embodiment in that the corner of the upper portion of the field plate electrode FP remains protruded. Thus, the electric field easily concentrates on the protruded portions, and leakage current is easily caused between the field plate electrode FP and the gate electrode GE described later. Also, there is a risk of deterioration of dielectric breakdown of the insulating film IF2.

On the other hand, in the first embodiment, the chemical dry etching process of FIG. 12 is applied, and thus, the corner of the upper portion of the field plate electrode FP is chamfered or rounded. Therefore, the concentration of the electric field is moderated, and therefore, the leakage current is suppressed, and the deterioration of the dielectric breakdown of the insulating film IF2 is also suppressed. Therefore, the reliability of the semiconductor device 100 can be improved.

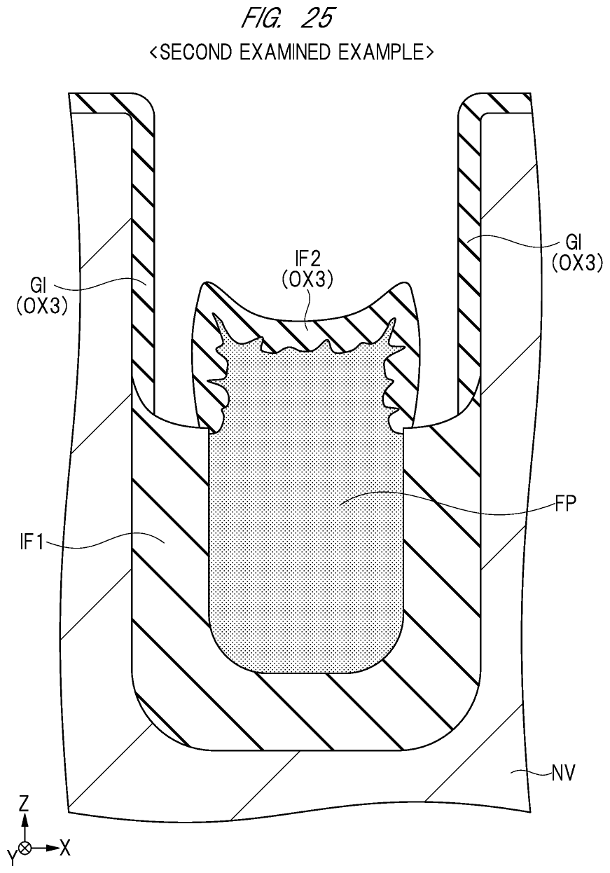

FIG. 25 illustrates a step of manufacturing the gate insulating film GI and the insulating film IF2 according to a second examined example. While the dry oxidization process is applied in the first embodiment, a wet oxidization process is applied in the second examined example. The wet oxidization process is, for example, a thermal oxidization process using moisture under a condition that is equal to or higher than 850° C., and that is equal to or lower than 950° C.

The impurity concentration of the polycrystalline silicon film configuring the field plate electrode FP is higher than the impurity concentration of the drift region NV. Therefore, in the wet oxidization process, the insulating film IF2 is easily made thicker than the gate insulating film GI by influence of enhanced oxidization.

Meanwhile, in the wet oxidization process, roughness of the oxidized surface of the field plate electrode FP is easily made larger. Thus, the insulating film IF2 is locally and easily thinner, and the electric field easily concentrates on the thinner portion. Also, it is difficult to moderate the concentration of the electric field at the protruded corner of the field plate electrode FP.

On the other hand, the influence of the enhanced oxidization is less in the dry oxidization process in the first embodiment than the wet oxidization process. However, the roughness of the oxidized surface of the field plate electrode FP is improved. Therefore, the concentration of the electric field is easily moderated.

As described above, in the first embodiment, the concentration of the electric field can be suppressed only by the chemical dry etching process on the field plate electrode FP. However, when the insulating film IF2 is also formed by the dry oxidization process, the concentration of the electric field can be further suppressed.

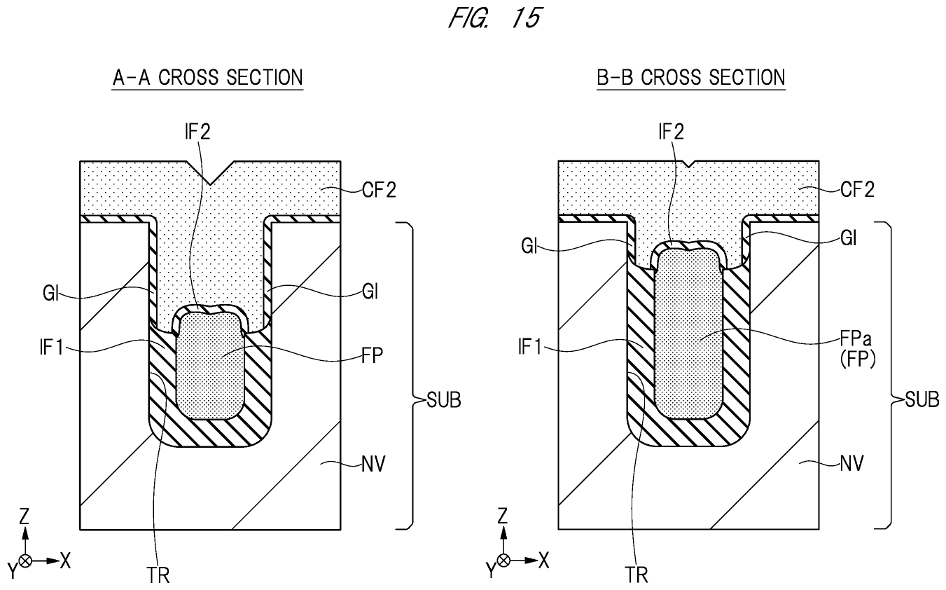

FIG. 15 illustrates a manufacturing step, continued from FIG. 14. As illustrated in FIG. 15, the conductive film CF2 is formed on the upper surface TS of the semiconductor substrate SUB to fill inside the trench TR by, for example, a CVD method. The conductive film CF2 is, for example, an n-type polycrystalline silicon film.

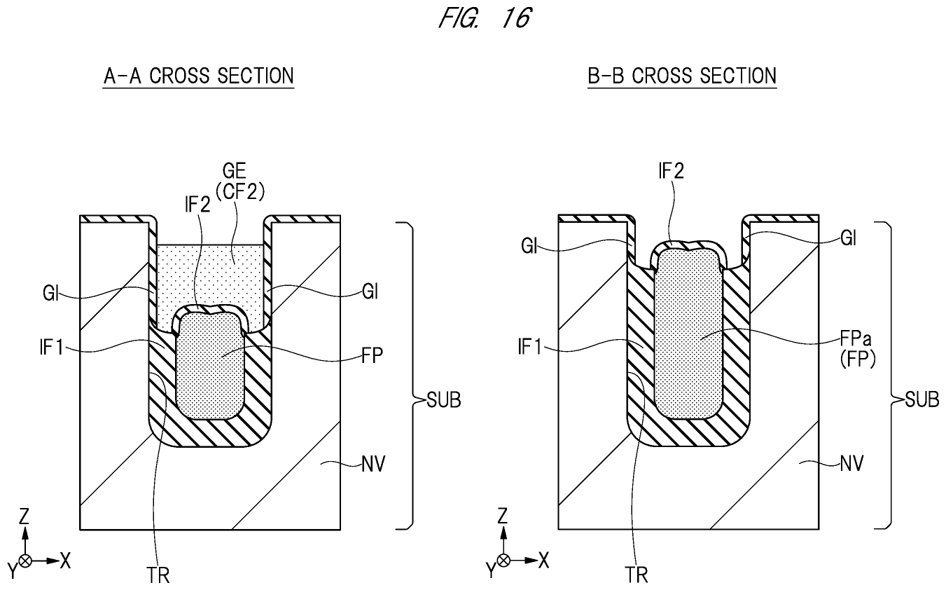

As illustrated in FIG. 16, when an anisotropic dry etching process is performed to the conductive film CF2, the conductive film CF2 formed outside the trench TR is removed. In this manner, as illustrated in the cross section on A-A, inside the trench TR, the gate electrode GE is formed on the field plate electrode FP via the insulating film IF2.

As illustrated in the cross section on B-B, the conductive film CF2 is removed inside the trench TR where the contact portion FPa is formed. The anisotropic dry etching process is performed in an over-etching manner in order to remove the unnecessary conductive film CF2 on the contact portion FPa, and thus, the upper surface of the gate electrode GE is slightly lower than the upper surface TS of the semiconductor substrate SUB. At this time, the semiconductor substrate SUB, the gate electrode GE and the field plate electrode FP (contact portion FPa) located inside the trench TR are electrically insulated from one another.

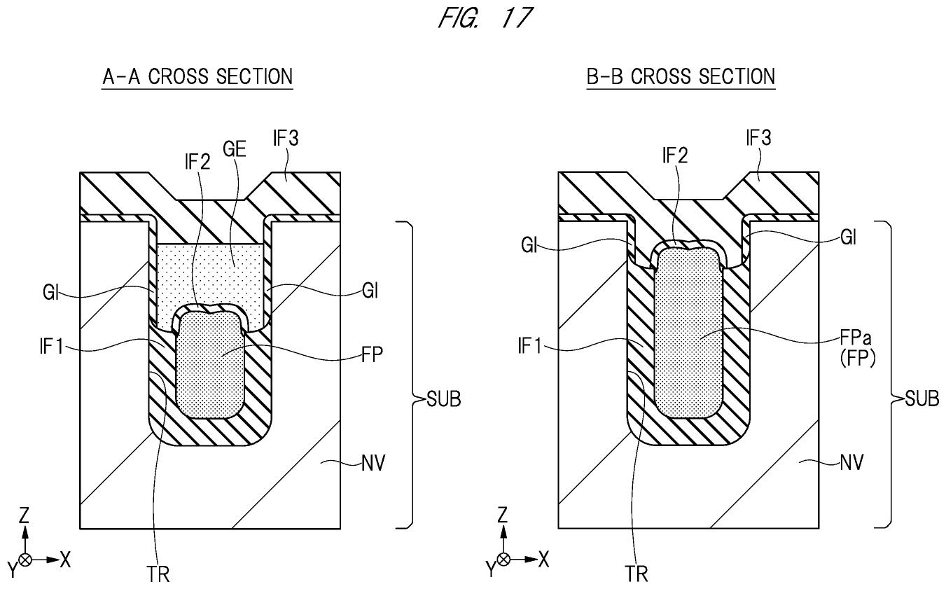

As illustrated in FIG. 17, an insulating film IF3 is formed on the upper surface TS of the semiconductor substrate SUB to cover the trench TR by, for example, a CVD method. The insulating film IF3 is, for example, a silicon oxide film.

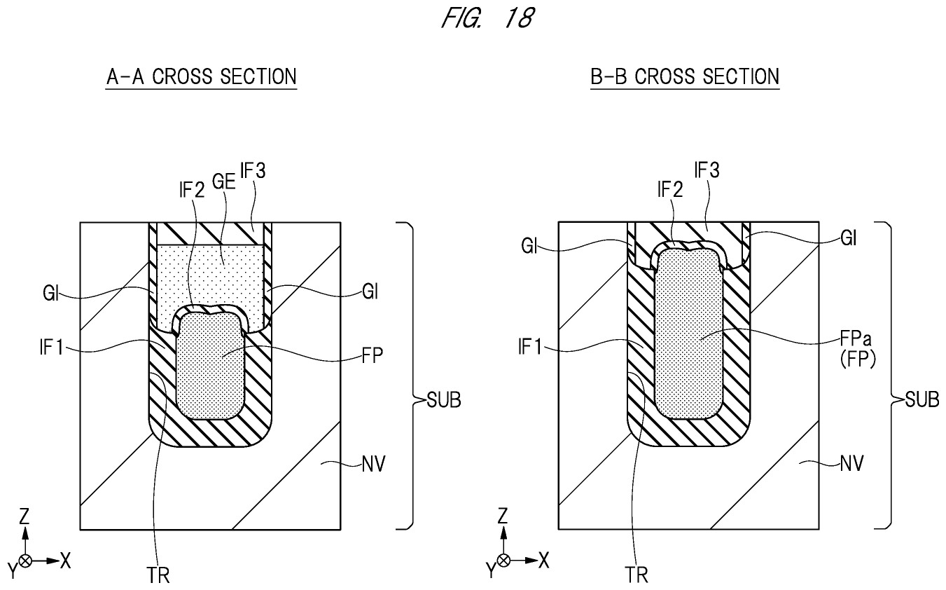

As illustrated in FIG. 18, by an anisotropic etching process, the insulating film IF3 and the gate insulating film GI on the upper surface TS of the semiconductor substrate SUB are removed. A part of the insulating film IF3 is left inside the trench TR.

Note that the formation of the insulating film IF3 is not essential. However, other semiconductor element can be formed in other region of the semiconductor substrate SUB by use of the insulating film IF3 as a protective film covering the trench TR. As the other semiconductor element, for example, a resistive element connecting the gate pad GP and the gate wiring GW can be exemplified. Between the manufacturing step of FIG. 17 and the manufacturing step of FIG. 18, the resistive element can be formed by forming and patterning a conductive film on the insulating film IF3.

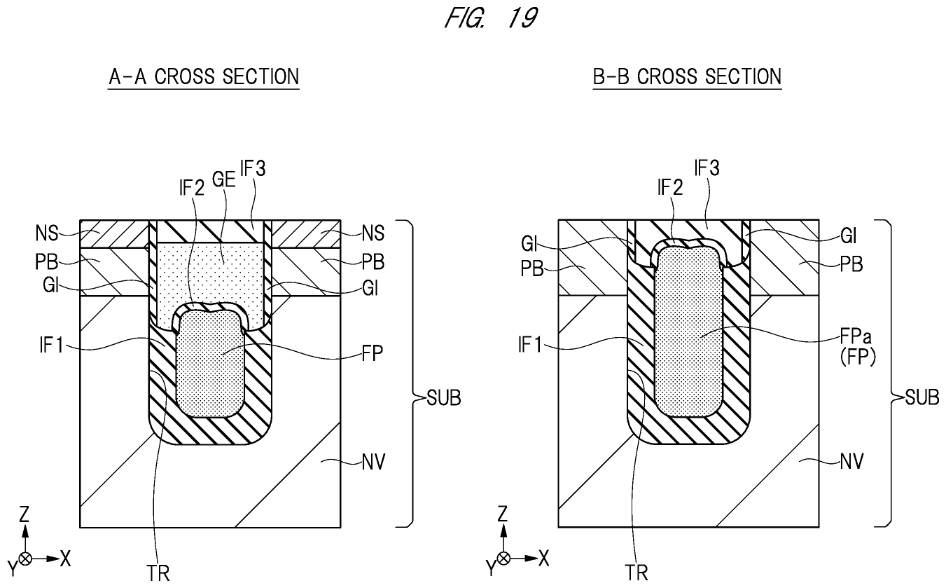

As illustrated in FIG. 19, the upper surface TS of the semiconductor substrate SUB is doped with, for example, boron (B) by a photolithography technique and an ion implantation method, so that a p-type body region PB is selectively formed in the semiconductor substrate SUB. The body region PB is made shallower than the trench TR.

Next, the semiconductor substrate is doped with, for example, arsenic (As) by a photolithography technique and an ion implantation method, so that an n-type source region NS is selectively formed in the body region PB in the cell region CR. Note that the n-type source region NS is not formed in the body region PB adjacent to the contact portion FPa. Then, a heat process is performed to the semiconductor substrate SUB to diffuse the impurities contained in the source region NS and the body region PB.

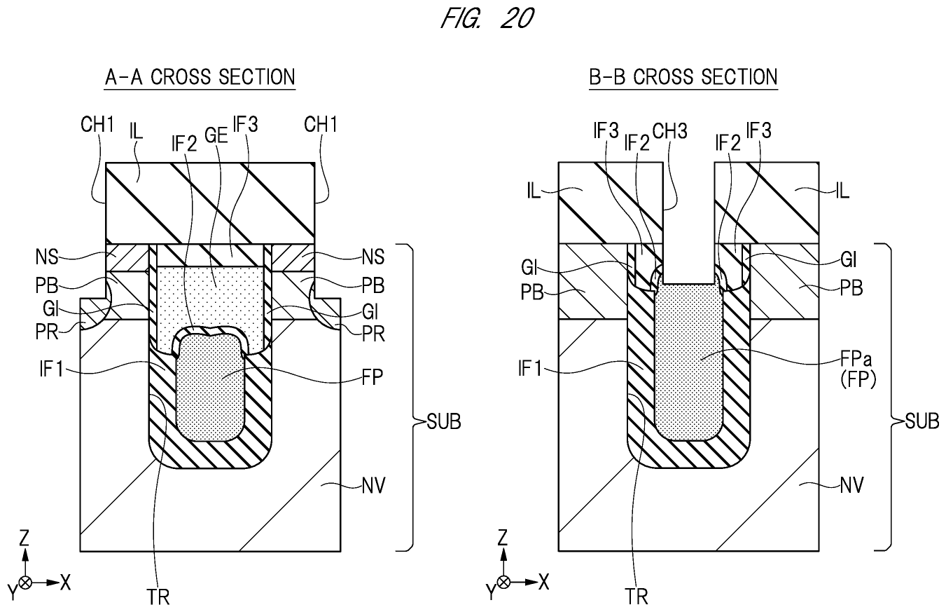

As illustrated in FIG. 20, an interlayer insulating film IL is formed on the upper surface TS of the semiconductor substrate SUB to cover the trench TR by, for example, a CVD method. The interlayer insulating film IL is made of, for example, a silicon oxide film. Note that the interlayer insulating film IL may be a stacked film made of a thin silicon oxide film formed by a CVD method and a phosphorous silicate glass (PSG) film or a boro-phospho silicate glass (BPSG) film formed by a coating method.

Next, the holes CH1 to CH3 are formed in the interlayer insulating film IL. First, a resist pattern having a pattern for opening the semiconductor substrate SUB where the source region NS is formed is formed on the interlayer insulating film IL. Next, by an anisotropic etching process using the resist pattern as a mask, the hole CH1 which penetrates through each of the interlayer insulating film IL and the source region NS and reaches inside the body region PB is formed. Next, the body region PB at the lower portion of the hole CH1 is doped with, for example, boron (B) by an ion implantation method, so that the p-type high-concentration diffusion region PR is formed. Then, the resist pattern is removed by an ashing process.

Next, a resist pattern having a pattern for opening upper sides of the contact portion FPa and the gate electrode GE is formed on the interlayer insulating film IL. Next, by an anisotropic etching process using the resist pattern as a mask, the hole CH3 which penetrates through the interlayer insulating film IL, the insulating film IF3 and the insulating film IF2 and reaches the contact portion FPa and the hole CH2 which penetrates through each of the interlayer insulating film IL and the insulating film IF3 and reaches the gate electrode GE are formed. Then, the resist pattern is removed by an ashing process.

Regarding an order of the formations of the holes CH1 to CH3, note that any hole may be formed first.

As illustrated in FIG. 20, the plugs PG are formed inside the holes CH1 to CH3, respectively, and the source electrode SE and the gate wiring GW are formed on the interlayer insulating film IL.

First, a first barrier metal film is formed inside the holes CH1 to CH3 and on the interlayer insulating film IL by a sputtering method or a CVD method. The first battier metal film is, for example, a stacked film made of a titanium nitride film and a titanium film. Next, a first conductive film is formed on the first barrier metal film by a CVD method. The first conductive film is made of, for example, a tungsten film. Next, the first barrier metal film and the first conductive film formed outside the holes CH1 to CH3 are removed by a CMP method or an anisotropic etching process. In this manner, the plugs PG made of the first barrier metal film and the first conductive film are formed to fill insides of the holes CH1 to CH3.

Next, a second barrier metal film is formed on the interlayer insulating film IL by a sputtering method. The second barrier metal film is made of, for example, a titanium tungsten film. Next, a second conductive film is formed on the second barrier metal film by a sputtering method. The second conductive film is, for example, an aluminum alloy film to which copper or silicon is added. Next, the second barrier metal film and the second conductive film are patterned to form the source electrode SE and the gate wiring GW.

Next, although not illustrated here, a protective film made of, for example, a polyimide film is formed on the source electrode SE and the gate wiring GW by, for example, a coating method. A part of the protective film is opened to expose regions which are to be the source pad SP and the gate pad GP in the source electrode SE and the gate wiring GW.

Then, the structure illustrated in FIG. 5 is provided through the following manufacturing steps. First, the lower surface BS of the semiconductor substrate SUB is polished as needed. Next, the lower surface BS of the semiconductor substrate SUB is doped with, for example, arsenic (As) or the like by an ion implantation method, so that the n-type drain region ND is formed. When the semiconductor substrate SUB is made of a stacked structure of an n-type silicon substrate and an n-type semiconductor layer, the drain region ND is made of the high-concentration n-type silicon substrate, and thus, the formation of the drain region ND by the ion implantation method can be omitted. Next, the drain electrode DE is formed on the lower surface BS of t the semiconductor substrate SUB by a sputtering method.

### Second Embodiment

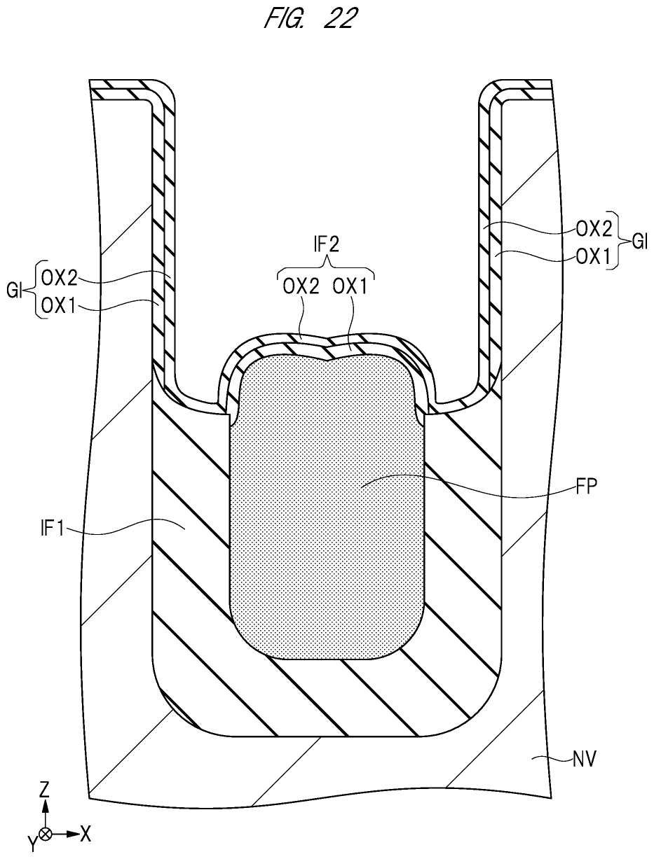

A semiconductor device according to a second embodiment will be described below with reference to FIG. 22. In the following explanation, note that differences from the first embodiment will be mainly described, and description of overlapping points with the first embodiment will be omitted.

In the first embodiment, each of the gate insulating film GI and the insulating film IF2 is made of the silicon oxide film OX1. As illustrated in FIG. 22, in the second embodiment, each of the gate insulating film GI and the insulating film IF2 is a stacked film including the silicon oxide film OX1 and a silicon oxide film OX3. Note that FIG. 22 illustrates a manufacturing step in place of the manufacturing step of FIG. 14 of the first embodiment.

As illustrated in FIG. 22, first, the silicon oxide film OX1 is formed on the insulating film IF1 located inside the trench TR, and the silicon oxide film OX1 is formed on the upper surface of the field plate electrode FP and also side surface of the field plate electrode FP which are exposed from the insulating film IF1. The silicon oxide film OX1 is formed by a dry oxidization process. The dry oxidization process is a thermal oxidization process using, for example, oxygen gas under a condition that is equal to or higher than 1000° C., and that is equal to or lower than 1200° C. as similar to the first embodiment. A thickness of the silicon oxide film OX1 according to the second embodiment is, for example, equal to or larger than 25 nm and equal to or smaller than 35 nm.

Next, by a CVD method, a silicon oxide film OX2 is formed on the silicon oxide film OX1. The silicon oxide film OX2 is a tetra ethoxy silane (TEOS) film, and has a thickness that is, for example, equal to or larger than 25 nm and equal to or smaller than 35 nm. Then, a heat process for densifying film texture of the silicon oxide film OX2 may be performed. Such a heat process is performed in, for example, nitrogen gas atmosphere or oxygen gas atmosphere at a temperature that is equal to or higher than 900° ° C., and that is equal to or lower than 1000° C.

The silicon oxide film OX2 formed by a CVD method is easier to be formed to have a uniform thickness than the silicon oxide film OX3 formed by a wet oxidization process as in the second examined example. Thus, the insulating film IF2 is difficult to be locally thinner, and the concentration of the electric field can be easily suppressed from occurring.

The total thickness of the insulating film IF2 is also easily adjusted by the silicon oxide film OX2. Thus, for example, the dielectric breakdown between the gate electrode GE and the field plate electrode FP can be easily improved when the silicon oxide film OX2 is made thick.

The number of layers of the silicon oxide films stacked on the silicon oxide film OX1 by the CVD method is not limited to one that is the silicon oxide film OX2, and a plurality of films may be stacked.

Not the silicon oxide film OX2 but the silicon oxide film OX1 is preferable as the insulating film being in contact with the field plate electrode FP and the semiconductor substrate SUB. The silicon oxide film OX1 formed by the dry oxidization process can improve the interface state between the insulating film IF2 and the field plate electrode FP and the interface state between the gate insulating film GI and the semiconductor substrate SUB more than the silicon oxide film OX2 formed by the CVD method.

In the foregoing, the present invention has been concretely described on the basis of the embodiments. However, the present invention is not limited to the foregoing embodiments, and various modifications can be made within the scope of the present invention.

What is claimed is:

1. A method of manufacturing a semiconductor device, comprising steps of:
(a) preparing a semiconductor substrate of a first conductive type, the semiconductor substrate having an upper surface and a lower surface;
(b) after the step of (a), forming a trench in the semiconductor substrate at the upper surface of the semiconductor substrate;
(c) after the step of (b), forming a first insulating film inside the trench and on the upper surface of the semiconductor substrate;
(d) after the step of (c), forming a field plate electrode on the first insulating film located inside the trench;
(e) after the step of (d), thinning the first insulating film, and exposing an upper portion of the field plate electrode from the first insulating film;
(f) after the step of (e), performing an isotropic etching process to the upper portion of the field plate electrode exposed from the first insulating film;
(g) after the step of (f), removing the first insulating film located on the upper surface of the semiconductor substrate, and recessing the first insulating film located inside the trench such that an upper surface of the first insulating film located inside the trench is positioned lower than the upper portion of the field plate electrode in cross-sectional view; and
(h) after the step of (g), in cross-sectional view, forming a gate insulating film inside the trench positioned over the upper surface of the first insulating film, and forming a second insulating film on an upper surface of the upper portion of the field plate electrode and on a side surface of the field plate electrode exposed from the first insulating film in the step of (g).

2. The method of manufacturing the semiconductor device according to claim 1,
wherein the field plate electrode is made of a polycrystalline silicon film, and
wherein the isotropic etching process in the step of (f) is a chemical dry etching process using CF4 gas.

3. The method of manufacturing the semiconductor device according to claim 2, wherein a corner of the upper portion of the field plate electrode is chamfered or rounded by the chemical dry etching process.

4. The method of manufacturing the semiconductor device according to claim 1,
wherein the first insulating film is made of a silicon oxide film, and
wherein each of the step of (e) and the step of (g) is performed with a wet etching process using a solution containing hydrofluoric acid.

5. The method of manufacturing the semiconductor device according to claim 1, wherein, in the step of (h), the gate insulating film and the second insulating film are formed by a thermal oxidization process using oxygen gas under a condition that is equal to or higher than 1000ºC, and that is equal to or lower than 1200° C.

6. The method of manufacturing the semiconductor device according to claim 1,
wherein the step of (h) includes steps of:
(h1) forming a first silicon oxide film inside the trench positioned over the first insulating film and on the upper surface of the field plate electrode and also the side surface of the field plate electrode which are exposed from the first insulating film by a thermal oxidization process using oxygen gas under a condition that is equal to or higher than 1000° C., and that is equal to or lower than 1200° C.; and
(h2) forming a second silicon oxide film on the first silicon oxide film by a CVD method, and
wherein each of the gate insulating film and the second insulating film includes the first silicon oxide film and the second silicon oxide film.

7. The method of manufacturing the semiconductor device according to claim 1,
wherein the step of (d) includes steps of:
(d1) forming a first conductive film on the first insulating film to fill inside of the trench;
(d2) after the step of (d1), forming the first conductive film remaining inside the trench as the field plate electrode by removing the first conductive film located outside the trench; and
(d3) after the step of (d2), selectively recessing the field plate electrode such that a part of the field plate electrode remains as a contact portion.

8. The method of manufacturing the semiconductor device according to claim 7, further comprising steps of:
(i) after the step of (h), inside the trench, forming a gate electrode on the field plate electrode recessed by the step of (d3) via the second insulating film;
(j) after the step of (i), on the upper surface of the semiconductor substrate, forming a body region inside the semiconductor substrate so as to be formed shallower than the trench, a conductive type of the body region being a second conductive type opposite the first conductive type;
(k) after the step of (j), forming a source region inside the body region, a conductive type of the source region being the first conductive type;
(l) after the step of (k), forming an interlayer insulating film on the upper surface of the semiconductor substrate so as to cover the trench;
(m) after the step of (l), forming a first hole penetrating through each of the interlayer insulating film and the source region, and reaching an inside of the body region;
(n) after the step of (l), forming a second hole penetrating through the interlayer insulating film, and reaching the gate electrode;
(o) after the step of (l), forming a third hole penetrating through the interlayer insulating film, and reaching the contact portion;
(p) after the step of (m), the step of (n) and the step of (o), forming each of a source electrode and a gate wiring on the interlayer insulating film; and
(q) after the step of (p), forming a drain electrode on the lower surface of the semiconductor substrate,
wherein the gate wiring is electrically connected to the gate electrode via the second hole,
wherein the source electrode is electrically connected to each of the source region and the body region via the first hole, and is electrically connected to the field plate electrode via the third hole, and
wherein the drain electrode is electrically connected to the semiconductor substrate.
